(19) United States
(12) Patent Application Publication
(10) Pub. No.: US 2018/0194633 A1
(43) Pub. Date: Jul. 12, 2018

(54) METHOD FOR THE THERMAL TREATMENT OF GRANULAR MATERIAL COMPOSED OF SILICON, GRANULAR MATERIAL COMPOSED OF SILICON, AND METHOD FOR PRODUCING A MONOCRYSTAL COMPOSED OF SILICON

(71) Applicant: SILTRONIC AG, Munich (DE)

(72) Inventor: Georg BRENNINGER, Oberbergkirchen (DE)

(73) Assignee: SILTRONIC AG, Munich (DE)

(21) Appl. No.: 15/742,306

(22) PCT Filed: Jul. 1, 2016
(86) PCT No.: PCT/EP2016/065465

§ 371 Date: Jan. 5, 2018

(30) Foreign Application Priority Data
Aug. 20, 2015 (DE) 10 2015 215 858.6

(51) Int. Cl. C01B 33/02; C30B 13/20; C30B 13/22; C30B 13/28; C30B 29/06; C30B 35/00

(52) U.S. Cl. CPC C01B 33/02; C30B 13/20; C30B 13/22; C01P 2002/60; C30B 29/06; C30B 35/007; C30B 13/28

(57) ABSTRACT

Granular silicon which is especially useful in reducing dislocations and gas inclusions of single crystals prepared therefrom is produced by a heat treatment in which a process gas flowing through a plasma chamber heats granular silicon, and the heated granular silicon is transported counter-currently through the plasma chamber, melting an outer periphery of the granular silicon, which then recrystallizes, producing an exterior with a lower concentration of crystal grains than the interior of the granules.

### CROSS REFERENCE TO RELATED APPLICATIONS

This application is the U.S. National Phase of PCT Appln. No. PCT/EP2016/065465 filed Jul. 1, 2016, which claims priority to German Application No. 10 2015 215 858.6 filed Aug. 20, 2015, the disclosures of which are incorporated in their entirety by reference herein.

### BACKGROUND OF THE INVENTION

### 1. Field of the Invention

The invention relates to a process for heat treatment of granular silicon composed of polycrystalline grains, to a process for producing a silicon single crystal in the course of which heat-treated granular silicon is employed, and to heat-treated granular silicon.

### 2. Description of the Related Art

Granular silicon is typically generated by depositing silicon in a fluidized bed. WO 2014/191274 is one of many publications addressing the production process. According to this publication, the generated granular silicon composed of polycrystalline grains may be used directly as a raw material for producing a silicon single crystal.

US 2005/0135986 A1 proposes a production process for granular silicon which gives rise to comparatively little fine dust and generates granular silicon, the respective polycrystalline grains of which have a comparatively smooth surface. The low propensity for dust formation is a property which becomes particularly important when the intention is to use the granular silicon to produce a silicon single crystal. If particles remain after the melting of the granular material and if they proceed to the interface at which the single crystal is growing, the particles can bring about the formation of dislocations. Generally, the crystallization process must then be aborted.

US 2013/0295385 A1 discloses a production process for granular silicon which can also be used for producing silicon single crystals, according to the “GFZ” process. The GFZ process is a development of the FZ process (float zone crystal growth) where the single crystal grows at the interface of a melt zone which is maintained by continued melting of a polycrystalline feed rod by means of an induction heating coil and lowering of the growing single crystal. In the GFZ process, granular silicon takes the place of the feed rod. US 2011/0185963 A1 describes a GFZ process where an induction heating coil is employed especially to melt the granular material.

It has been determined that there is a continuing need to improve the properties of granular silicon. There is in particular a need to modify granular silicon so as to reduce its propensity to leave behind, in the molten state, particles and gas inclusions in the melt. Deriving therefrom is the need for a modified GFZ process which exhibits low dislocation rates and with which silicon single crystals that are ideally free of gas inclusions may be produced. It is these problems which the present invention addresses.

FIG. 1 is a schematic diagram of the construction of an apparatus suitable for carrying out the production of a silicon single crystal according to a particularly preferred embodiment of the invention.

FIG. 2 is a schematic representation of the construction of a particularly preferred embodiment of the preheating stage.

FIG. 3 is a schematic representation of the construction of a particularly preferred embodiment of the plasma chamber.

FIGS. 4 to 8 show SEM images of grains of granular silicon.

### SUMMARY OF THE INVENTION

The invention pertains to a process for heat treatment of granular silicon composed of polycrystalline grains, comprising passing a process gas along a flow direction through a plasma chamber;

generating a plasma zone in the plasma chamber;
maintaining the plasma zone by supplying microwave radiation into the plasma chamber;
preheating the granular silicon via the process gas to a temperature of not less than 900° C.;
transporting the preheated granular silicon through the plasma chamber and the plasma zone counter to the direction of flow of the process gas to temporarily melt an outer region of the grains; and
collecting the plasma-treated granular silicon. The invention also pertains to a process for producing a silicon single crystal, comprising
forming a melt zone having an interface at which a silicon single crystal grows;
passing a process gas along a flow direction through a plasma chamber;
generating a plasma zone in the plasma chamber;
maintaining the plasma zone by supplying microwave radiation into the plasma chamber;
preheating granular silicon composed of polycrystalline grains via the process gas to a temperature of not less than 900° C.;
transporting the preheated granular silicon through the plasma chamber and the plasma zone counter to the direction of flow of the process gas to temporarily melt an outer region of the grains;
induction melting the plasma-treated granular silicon; and supplying the molten granular material to the melt zone. The invention further pertains to granular silicon composed of polycrystalline grains each comprising: a surface, a peripheral region and a core region, wherein the crystal density in the peripheral region is lower than the crystal density in the core region.

### DETAILED DESCRIPTION OF THE PREFERRED EMBODIMENTS

The invention is based on the realization that measures limited to improving the properties of granular silicon by optimization of the production thereof by deposition of silicon in a fluidized bed are not sufficient.

Following on from this realization, it is proposed to heat the granular silicon, after the production thereof, via a treatment with plasma to a temperature higher than the melting point of silicon. In the course of this heat treatment the polycrystalline grains of the granular material are melted in a peripheral region (outer region), while a core region (inner region) remains in the solid state. During subsequent cooling of the grains the peripheral region recrystallizes but with an altered polycrystalline structure. The crystal density (number of crystals per unit volume) is markedly lower in the peripheral region than in the core region. The roughness of the surface of the grains is moreover reduced. This is evident even upon visual inspection of the plasma-treated granular silicon from its luster which increases on account of the treatment. The structural alteration of the granular silicon is also accompanied by an observable improvement in its properties. When the inventive silicon is used for producing a single crystal, there is a fall in dislocation rates and also the incidence of gas inclusions in the single crystal.

Granular silicon suitable for the proposed treatment with plasma is composed of polycrystalline grains and is preferably produced by deposition of silicon on particles of silicon in the presence of a silicon-containing reaction gas in a fluidized bed reactor. The reaction gas comprises silane or a chlorine-comprising silane, preferably trichlorosilane. An example of a production process that may be used is that described in WO 2014/191274 A1. It is preferable when not less than 98% (by weight) of the granular material is composed of grains having a spheroid shape whose grain size, expressed in terms of the screen diameter as the equivalent diameter, is preferably 600 to 8000 μm, more preferably 600 to 4000 μm. The granular silicon preferably comprises not more than 50 ppb (by weight) of metallic impurities.

Due to the use chlorine-comprising reaction gas during its preparation, the granular silicon can comprise chlorine as an impurity. When such granular silicon is subjected to the proposed treatment with plasma this treatment also has the effect that the concentration of chlorine in the treated granular silicon is significantly lower than in the untreated granular silicon. The concentration of chlorine in the granular silicon treated in accordance with the invention can be reduced by more than 50%. The concentration is greater in the core region of the granular material than in the peripheral region. The reduction in the concentration of chlorine in the granular silicon increases with decreasing average grain diameter of the granular material. The same also applies for other impurities that are volatile at the temperature of the heat treatment.

The proposed treatment of the granular silicon with plasma is preferably effected under a pressure in the range of atmospheric pressure, in particular under a pressure in the range from 50,000 Pa to 150,000 Pa. The granular silicon is preheated in a preheating stage to a temperature of not less than 900° C. and subsequently transported through a plasma zone having a temperature above the temperature of the melting point of silicon. Even a short residence time in the plasma zone is sufficient to bring about near-surface melting of the respective grains of the granular silicon. The molten region recrystallizes immediately after exiting the plasma zone.

The generating and maintaining of the plasma zone is preferably accomplished using an apparatus known per se, for example using an apparatus described in DE 103 27 853 A1. Such an apparatus comprises a microwave generator, a plasma chamber, microwave guides for supplying microwave radiation to the plasma chamber and an ignition device for igniting the plasma. Particular preference is given to using an apparatus described in WO 2015/014839 A1 because this allows the energy supplied via the microwave radiation to be uniformly distributed in the plasma chamber even at higher outputs. The microwave radiation is preferably introduced to the plasma chamber via waveguides at at least two mutually opposite points. The frequency of the microwave radiation is preferably in the range from 0.9 GHz to 10 GHz, for example 2.45 GHz. After the igniting of the plasma the plasma zone spreads out in the plasma chamber along the longitudinal axis thereof.

The granular silicon is preheated by process gas. The process gas is passed through the plasma chamber and is itself heated there in the plasma zone. Part of the absorbed heat is subsequently transferred to the granular silicon to preheat the granular silicon. It is preferable when at least part of the process gas is recirculated, i.e. after the preheating of the granular silicon, at least part of the process gas is recycled to a gas inlet into the plasma chamber.

The process gas is preferably passed into the plasma chamber via a lower gas inlet and preferably exits the plasma chamber via an upper gas outlet. At the gas inlet the process gas is preferably passed into the plasma chamber tangentially and therefore flows turbulently along a flow direction through the plasma chamber to the gas outlet. Preheated granular silicon is transported through the plasma zone counter to the direction of flow of the process gas. The granular silicon is preferably allowed to fall through the plasma zone. The turbulence of the process gas lengthens the transport path of the granular silicon in the plasma zone and the residence time thereof in the plasma zone. The inner wall of the plasma chamber is made of a dielectric material, preferably of quartz or ceramic. After exiting the plasma chamber the process gas flows into a preheating stage for granular silicon and from there preferably back to the gas inlet into the plasma chamber.

The process gas is composed of air or a constituent of air or a mixture of at least two constituents of air or of hydrogen or of a mixture of hydrogen and at least one inert gas. A preferred process gas has inert or reducing character. A particularly preferred process gas is argon or a mixture of argon and hydrogen, wherein the proportion of hydrogen should preferably be not more than 2.7% (by volume). A process gas having a reducing character removes an oxide layer on the surface of the grains of which the granular silicon is composed.

The preheating stage is preferably a tube from where the granular silicon can fall into the plasma zone continuously or discontinuously. The granular silicon is preheated by process gas that ascends into the tube. A heating means may optionally be present which additionally effects external heating of the tube and the granular silicon present therein. Particular preference is given to arranging baffles in the tube which form a cascade of steps which lengthen the transport path of granular silicon through the tube. This also lengthens the residence time of the granular material in the tube so that more time for preheating the granular silicon in the preheating stage is available. The tube and any baffles are preferably made of a material which contaminates the granular silicon with metals only to a small extent, if at all, upon contact. The material is preferably quartz or ceramic.

The granular silicon is conveyed from a reservoir vessel into the preheating stage and falls counter to the direction of the ascending process gas first through the preheating stage, subsequently through the plasma zone and finally to a target location, for example into a receiving vessel or into a crucible or onto a dish or onto a conveyor belt.

The plasma-treated granular silicon is composed of grains having a polycrystalline structure. The polycrystalline structure comprises a multiplicity of crystals and common interfaces between adjacent crystals.

The surface of the grains is smooth and lustrous provided that an inert or reducing gas was employed as the process gas and that the granular silicon was not exposed to an oxidizing atmosphere such as ambient air after the treatment with plasma. The polycrystalline structure of the grains in the peripheral region is distinct from the polycrystalline structure of the grains in the core region. The peripheral region in each case extends from the surface of the grains to the inside of the grains. The crystals are markedly larger in the peripheral region than in the core region. The crystal density (number of crystals per unit volume) is accordingly lower in the peripheral region than in the core region. In the peripheral region the crystal density is preferably not more than 20% of the crystal density in the core region, more preferably not more than 2%. The thickness of the peripheral region is preferably not less than 20 μm, more preferably not less than 40 μm. Between the peripheral region and the core region there is a transition region in which the crystal density is greater than in the peripheral region and smaller than in the core region.

The particular polycrystalline structure of the grains imparts the plasma-treated granular silicon with the property of being particularly suitable for the production of single crystals. The potential of the plasma-treated granular silicon to be able to become a source of fine dust and gas inclusions is markedly reduced.

The plasma-treated granular silicon is therefore preferably used for producing silicon single crystals (preferably by means of a CZ process or a GFZ process) or polycrystalline bodies therewith. The produced single crystals or polycrystalline bodies are in turn used in particular as precursors for producing electronic or optoelectronic components or solar industry components.

According to a preferred embodiment of the invention the plasma-treated granular silicon is melted and crystallized to afford a single crystal without previously having been exposed to an oxidizing atmosphere. It is particularly preferable when the granular silicon in the plasma-treated state is melted in accordance with a GFZ process and the melt thus formed is subsequently crystallized to afford a single crystal. To this end, after exiting the plasma chamber the plasma-treated granular silicon is transported under a nonoxidizing atmosphere, preferably under argon or under a mixture of argon and hydrogen, more preferably under a nonoxidizing atmosphere having the composition of the process gas employed during the treatment with plasma, into an apparatus for crystal growth. The apparatus comprises a crucible or a dish. In the latter case, the plasma-treated granular silicon is subjected to induction melting and in a molten state is sent to a melt zone having an interface at which a single crystal grows. No oxide layer need be dissolved during melting of the plasma-treated granular material and particle formation problems connected therewith are avoided. Particular preference is given to using an apparatus for crystal growth equipped with an induction heating coil provided especially for melting the granular silicon. Such an induction heating coil is disclosed in US 2011/0185963 A1 for example. To generate the melt zone, solid silicon which temporarily covers an opening in the center of a crucible or dish is initially melted and the molten silicon brought into contact with a seed crystal. It is also preferable when the plasma-treated granular silicon still has a temperature of not less than 600° C., more preferably not less than 800° C., on account of the treatment with plasma when the melting of the plasma-treated granular silicon and the supplying thereof to the melt zone is commenced. This reduces the burden on the induction heating coil for melting the plasma-treated granular silicon and shortens the duration of the single-crystal production.

The invention is hereinbelow more particularly elucidated with reference to drawings.

The apparatus of FIG. 1 is divided into a device for treatment of granular silicon with plasma and a device for producing a single crystal according to the GFZ process using the plasma-treated granular silicon.

The device for treatment of granular silicon with plasma comprises a reservoir vessel 1 for granular silicon to be treated, a metering apparatus 2 for metering granular silicon into a preheating stage 3 in which the granular silicon to be treated is preheated, a plasma chamber 4 in which a plasma zone 5 is ignited and is maintained by means of microwave radiation, a generator 6 for generating the microwave radiation and a conveying conduit 7 for conveying plasma-treated granular silicon 8 into the device for producing a single crystal according to the GFZ process. This device comprises an induction heating coil 9 for melting the granular material 8 on a dish 10, wherein the induction coil 9 has an opening through which the granular material 8 falls onto the dish 10 where it is melted in order in the molten state to proceed from there, through an opening in the center of the dish 10, to a melt zone which is maintained by an induction heating coil 11. The melt zone has an interface at which a single crystal 12 grows and is continuously lowered. Via a conduit 17, process gas exiting the preheating stage 3 is recycled to a gas inlet into the plasma chamber 4.

The preheating stage 3 represented schematically in FIG. 2 comprises a tube 13 having built in baffles 14. Granular silicon to be treated is conveyed into an upper region of the tube 13 and falls initially onto the baffles 14 and finally, out of a lower opening 15 in the tube 13, into the plasma chamber 4. Process gas is passed counter to the fall direction of the granular silicon from bottom to top through the tube 13.

The plasma chamber 4 according to FIG. 3 comprises waveguides 16 for introducing microwave radiation in the direction of the broad arrows and for maintaining the plasma zone 5 inside the plasma chamber 4, an ignition device 18 for generating the plasma zone 5 and a receiving vessel 19 for collecting plasma-treated granular material. Process gas is passed in the direction of the slender arrow through the conduit 17 to a lower gas inlet into the plasma chamber and flows through the plasma zone 5 to an upper gas outlet out of the plasma chamber.

FIG. 4 shows the SEM image of part of the surface of a grain of granular silicon treated with plasma in accordance with the invention. The figure shows the surfaces of crystals 20 and common interfaces 21 between adjacent crystals. For comparison, FIG. 5 depicts part of the surface of a grain of granular silicon in the state before treatment with plasma in accordance with the invention.

FIG. 6 shows the SEM image of a segment of a section through a grain of granular silicon treated with plasma in accordance with the invention. The segment extends from the surface 22 of the grain into the interior of the grain. A near-surface peripheral region 23 of the grain is characterized by crystals 24 which are comparatively large while the crystals in a core region 25 of the grain are comparatively small. For comparison, FIG. 7 depicts a corresponding image of a grain of granular silicon in the state before treatment with plasma in accordance with the invention.

The SEM image of FIG. 8 shows a segment of the surface and a segment of the section face through a grain of granular silicon treated with plasma in accordance with the invention. The image shows an edge 26 between the surface 22 and the section face and crystals 24 in the peripheral region 23 of the grain which are comparatively large.

Granular silicon comprising chlorine as an impurity and having an average grain diameter of 1 mm in the state after the heat treatment according to the invention was compared with corresponding granular material in the state before the heat treatment according to the invention. The concentration of chlorine in the granular silicon produced in accordance with the invention was 56% lower than in the comparative granular material.

1.-13. (canceled)

14. A process for the heat treatment of granular silicon composed of polycrystalline grains, comprising
passing a process gas along a flow direction through a plasma chamber;
generating a plasma zone in the plasma chamber;
maintaining the plasma zone by supplying microwave radiation into the plasma chamber;
preheating the granular silicon in a preheating stage to a temperature of not less than 900° C. via the process gas from the plasma chamber to form preheated granular silicon;
transporting the preheated granular silicon through the plasma chamber and the plasma zone counter to the flow direction of the process gas, and temporarily melting an outer region of the granular silicon to form plasma-treated granular silicon; and
collecting the plasma-treated granular silicon.

15. The process of claim 14, further comprising:
induction melting the plasma-treated granular silicon and supplying the molten plasma-treated granular silicon to a melt zone having an interface at which a silicon single crystal grows.

16. The process of claim 1, wherein the process gas has a reducing property and an oxide layer is removed from the surface of the granular silicon during the heat treatment.

17. The process of claim 14, further comprising:
providing a transport path for the granular silicon through the preheating stage and providing baffles in the preheating stage, the presence of which lengthen the transport path of the granular silicon through the preheating stage.

18. The process of claim 14, comprising recycling the process gas to a gas inlet into the plasma chamber after the preheating of the granular silicon by the process gas.

19. The process of claim 16, wherein the plasma-treated granular silicon is transported from the plasma chamber, to a location where induction melting of the plasma-treated granular silicon takes place, in a nonoxidizing atmosphere.

20. The process of claim 15, wherein the plasma-treated granular silicon has a temperature of not less than 600° C. before the induction melting.

21. The process of claim 15, wherein the process gas has a reducing property and an oxide layer is removed from the surface of the granular silicon during the heat treatment, and wherein the plasma-treated granular silicon has a temperature of not less than 600° C. before the induction melting.

22. Granular silicon composed of polycrystalline grains, the granular silicon comprising:
a surface, a peripheral region and a core region, wherein a crystal density in the peripheral region is lower than a crystal density in the core region.

23. The granular silicon of claim 22, wherein the crystal density in the peripheral region is not more than 20% of the crystal density in the core region.

24. Granular silicon composed of polycrystalline grains, the granular silicon comprising:
a surface, a peripheral region and a core region, wherein a crystal density in the peripheral region is lower than a crystal density in the core region, the granular silicon comprising plasma-treated granular silicon produced by the process of claim 14.

25. The granular silicon of claim 22, wherein the peripheral region has a thickness of not less than 30 μm.

26. The granular silicon of claim 23, wherein the peripheral region has a thickness of not less than 30 μm.

27. The granular silicon of claim 22, wherein at least 98 wt. % of the grains have a grain size of 600 to 8000 μm.

28. The granular silicon of claim 22, which contains at least one impurity, wherein the concentration of the impurity in the core region is greater than in the peripheral region.

29. The granular silicon of claim 28, wherein chlorine is an impurity, and wherein the concentration of chlorine is at least 50% lower than the concentration that would be determined arithmetically if the concentration of chlorine in the peripheral region were the same as in the core region.
